(19) United States
(12) Patent Application Publication
(10) Pub. No.: US 2014/0336962 A1
(43) Pub. Date: Nov. 13, 2014

(54) Method and Apparatus for Estimating Remaining Operating Time

(71) Applicant: NOKIA CORPORATION, Espoo (FI)

(72) Inventors: Mikael Martti Vaino Vestama, Helsinki (FI); Jussi Pekka Olavi Ruutu, Espoo (FI)

(21) Appl. No.: 13/699,321

(22) PCT Filed: May 27, 2010
(86) PCT No.: PCT/IB2010/001269

§ 371 Date: May 5, 2014

(51) Int. Cl. G01R 31/36

(52) U.S. Cl. CPC G01R 31/3634
USPC 702/63

(57) ABSTRACT

In accordance with an example embodiment of the present invention, an apparatus comprising a status detector configured to identify status of a device powered by at least one battery, an energy management circuitry configured to at least perform estimating a remaining battery energy at a first time instant and a second time instant, calculating an average power consumption based at least on the measured remaining battery energy for at least the first time instant and the second time instant, and estimating a remaining operating time for the identified status based at least on the calculated average power consumption, wherein a single status of the device is identified from the first time instant to the second time instant.

### TECHNICAL FIELD

The present application relates generally to a power or energy management solution in battery powered devices, more specifically a method and apparatus for estimating remaining operating time of the devices.

### BACKGROUND

It is very common to indicate the remaining energy in battery powered electronic devices, for example, 5 to 7 level bars or a single extendable bar for mobile phone, a percentage in laptop. However, this may not be a convenient way to estimate the remaining operating time of the devices for consumers. It may happen sometimes that the battery is drained in the middle of an important conversion or some other activity. Consumers may want to know how long the battery can last if there are for example three bars left.

If the device can itself estimate and show the remaining operating time, the consumer can make better informed decisions when to recharge the device or how to use the device in order to get the battery last long enough. There exist various remaining operating times. For example how long the battery would last if the device is used in the “normal” way (in the way that the consumer normally uses it with a mix of use cases, such as telephone call, web browsing, messaging and so on). Alternatively, it is possible to express how long the consumer could use some certain functionality, for example, talk in a telephone call or play music.

One special case is the remaining idle time. This means how long the device can stay in idle (or stand-by) mode. Alternatively, if the consumer does not use the device actively, how long the battery lasts. This is important especially with telephone and messaging kind of use cases when the consumer wants to be reachable.

### SUMMARY

Various aspects of examples of the invention are set out in the claims.

According to a first aspect of the present invention, there is a provided apparatus comprising a status detector configured to identify status of a device powered by at least one battery, an energy management circuitry configured to at least perform estimating remaining battery energy at a first time instant and a second time instant, calculating an average power consumption based at least on the measured a remaining battery energy for at least the first time instant and the second time instant, and estimating a remaining operating time for the identified status based at least on the calculated average power consumption, wherein a single status of the device is identified from the first time instant to the second time instant.

According to a second aspect of the present invention, there is a provided method comprising identifying status of a battery, estimating a remaining battery energy at a first time instant and a second time instant, calculating an average power consumption rate based at least on the measured remaining battery energy, and estimating a remaining operating time for the identified status based at least on the calculated average power consumption rate, wherein a single status of the device is identified from the first time instant to the second time instant.

According to a third aspect of the present invention, there is a provided computer program product comprising a computer-readable medium bearing computer program code embodied therein for use with a computer, the computer program code comprising code for estimating a remaining battery energy at a first time instant and a second time instant, code for calculating an average power consumption based at least on the measured remaining battery energy for at least the first time instant and the second time instant, and code for estimating a remaining operating time for the identified status based at least on the calculated average power consumption, wherein a single status of the device is identified from the first time instant to the second time instant.

According to a fourth aspect of the present invention, there is a provided a means for identifying status of a device powered by at least one power storage means, a means for performing estimating a remaining energy of the power storage means at a first time instant and a second time instant, calculating an average power consumption based at least on the measured remaining battery energy for at least the first time instant and the second time instant, and estimating a remaining operating time for the identified status based at least on the calculated average power consumption, wherein a single status of the device is identified from the first time instant to the second time instant.

### BRIEF DESCRIPTION OF THE DRAWINGS

For a more complete understanding of example embodiments of the present invention, reference is now made to the following descriptions taken in connection with the accompanying drawings in which:

FIG. 1 shows a block diagram of a device comprising an apparatus for estimating remaining time of at least one battery in the device powered by the at least one battery according to an example embodiment;

FIG. 2 gives a flow diagram illustrating a method for estimating remaining idle time of a device powered by a battery according to an example embodiment;

FIG. 3 is a flow diagram illustrating a possible way for detecting the status of a device according to some example embodiments; and

FIG. 4 is a flow diagram showing operations for updating power consumption of a device when the status of the device is idle according to an example embodiment.

### DETAILED DESCRIPTION OF THE DRAWINGS

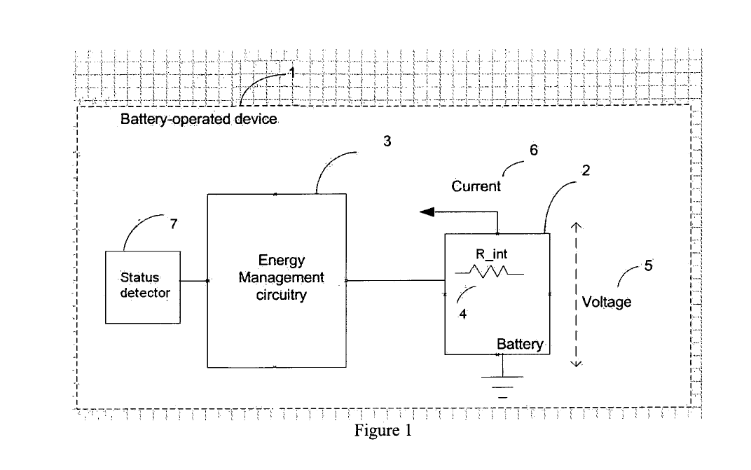

An example embodiment of the present invention and its potential advantages are understood by referring to FIG. 1 through FIG. 4 of the drawings.

FIG. 1 shows a block diagram of a device comprising an apparatus for estimating remaining idle time (RIT) of a battery-operated device according to an example embodiment. The battery-operated device 1 comprises at least one battery 2, an energy management circuitry (EM circuitry) 3, a status detector 7. For a purpose of modeling of a non-ideal battery, the at least one battery 2 has an internal resistance R_int 4. While it is not a real resistor component, it may be considered as a virtual resistor inside the at least battery 2 which creates the battery voltage drops when the electrical current is drawn. The EM circuitry 3 may include a memory (not shown in FIG. 1) for storing the energy management related measurement. The at least one battery 2 may be in a single battery type or different battery types. The memory in the EM circuitry 3 may also contain registers for storing the parameters specific to the type of the at least one battery 2. The EM circuitry 3 may be an independent circuitry whose sole purpose is to make energy management related measurements or functionality or may be integrated into some other chipsets. The EM circuitry 3 may also comprise the function of energy checking (i.e. detecting if the battery has been charged) and time check (collecting time information for different measurement steps). According to another example embodiment, the EM circuitry 3 may be external to the battery operated device 1 and communicate with the device 1 wirelessly or through some wired means. The status detector 7 has an interface with all the applications in the device 1 and identifies the status of the device 1 based on different criteria. The status detector 7 provides the status information of the device 1 to the EM circuitry 3. According to a third example embodiment, the EM circuitry 3 may comprise the status detector 7.

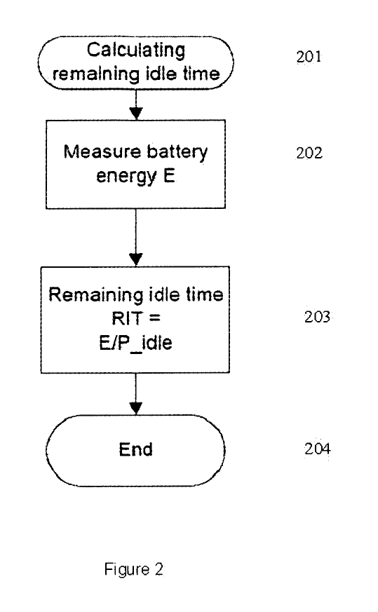

FIG. 2 illustrates the basic method for estimating RIT. First the amount of battery energy is obtained (e.g. in Joules or any other suitable units) in step 202. In the next step 203 the RIT can be obtained simply by dividing the remaining battery energy E by the idle power consumption P_idle. For example, if energy E is given in Joules and the idle power P_idle in Watts, the remaining idle time is then obtained in seconds. As the RIT is often long, it is good to convert the seconds into days or hours (and possibly minutes, too, if we want show more accuracy). The RIT information could be shown, for example, as “3 d 13 h 56 min”).

At least one goal of the invented method is to estimate remaining idle time. The device can be considered to be in idle status when the status detector 7 detects that the device 1 is not actively used by the user. The exact definition of idle status can vary depending on the device. For example, the device can do some background activity such as checking e-mails or updating content even without the active participation of the user. It should also be understood that the invented method is not only limited to idle use case but it also works with any other use cases. However, it is especially useful with those use cases that have small power consumption since the invented method does not require expensive instrumentation for accurate current measurements. According to an example embodiment, one possible way to determine if the device is in idle status is to check what application or process is on the foreground, for example, the application that has been the most visible for the user. In some devices there may be just one application filling most of the display area and/or other user interfaces (UI) while in the other devices the foreground application may be the one with UI control only (e.g. the control for screen in a mobile device). If the foreground application is a typical idle application, for example, a screensaver or the application that is used to navigate between open applications (i.e. an application selector), the device may be defined in idle mode. Depending on the device, the idle application (or process) may also be different from these two. It may be possible that the user can choose from many different applications what is to be used as idle application.

For some devices, it may look like the device is in idle mode as the idle application is on and the power consumption of device is low but there may be a non-idle application running in background such as Music Player. If it is possible to measure central processing unit (CPU) load correctly, the information of CPU load may tell us if the device is considered to be in idle mode by checking whether the CPU load of the device is low enough or below a CPU load threshold. The CPU load threshold may be, for example, 10% or 15% of the maximum load, and the value of the threshold may be of device dependence, for example based at least on CPU type, or implementation, or device and/or hardware setup.

The status of a device may also be determined by power consumption. The power consumption is obtained using known methods (power=voltage×current) and commonly available circuitries (e.g. EM circuitry 3) that are able to provide this information. If the power consumption of the device is high, this means that there is some heavy processing ongoing (in the background) although the foreground application might be an idle application. If the power consumption is above the so called power usage threshold, the device is said and/or set not to be in idle status (i.e. it is active status). Otherwise, the device is idle. It should be understood that all the above just give some examples and other methods/criteria or their combination may apply depending on the device.

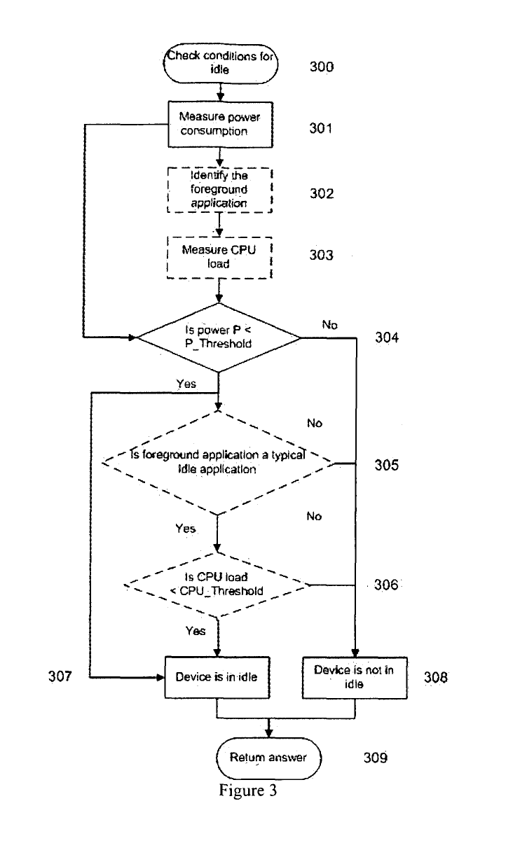

FIG. 3 shows a flow diagram illustrating a possible way for detecting idle status of a device according to some example embodiments. According to an example embodiment, in step 301 the power consumption is measured. In step 302, the foreground application is identified. In step 303, the CPU load is measured assuming that it is possible. If it is detected that the power consumption is less than the power usage threshold in step 304, a typical idle application is detected at the foreground in step 305 and it is detected that the CPU load is lower than the CPU load threshold in step 306, the device 1 is identified in idle status in step 307, otherwise not in idle status in step 308. If the device is not in idle status, the test for idle status needs to be done periodically. This can be done e.g. once a minute or some other implementation dependent time interval, until the status of the device has changed. It is also possible that the testing for idle status is based on events instead of time. In other words, e.g. the user can generate an event (such as a key press) that indicates the change of the device status to idle status or from idle status. The steps 301, 302 and 303 can be performed in any order or simultaneously. Also steps 305 and 306 can be performed in different order or simultaneously, if so desired. According to another example embodiment, step 301 and 304 (in solid-line boxes) can be performed alone for checking if the device is in idle status. Steps 302 and 305, steps 303 and 306 (in dashed-line boxes) are two pairs of optional steps and may be performed in combination with steps 301 and 304 respectively.

According to an example embodiment, the EM circuitry 3 measures voltage and current of the at least one battery 2. The energy consumption is estimated by:

Eₙ=Eₙ₋₁+P(tₙ)Δtₙ=Eₙ₋₁+V(tₙ)I(tₙ)Δtₙ,

where P(tₙ) is the power consumption at time tₙ, V(tₙ) and I(tₙ) represent the momentary measurement result of voltage and current at time tₙ, respectively, and Δtₙ an integrating step (i.e. the time difference between the consecutive measurement samples). The remaining battery energy E is obtained after the energy consumption is taken away from the initial battery energy. This method requires hardware support that allows accurate, real-time measurement and integration of current taken from the battery 2. When the device is idle, the current I(tₙ) is small and it is essential that the EM circuitry 3 is able to measure accurately also these small currents. However, often this is not the case or the EM circuitry 3 requires expensive calibration.

The remaining battery energy may be estimated in a way that does not require any long-term integration and monitoring of battery current, for example, estimating the remaining energy E of a battery based on a measurement of a momentary voltage and a momentary current or power. According to an example embodiment, E is defined as a function of its voltage U, where U is a function of power P owing to a characteristic function (E/U(P)), or in short: (E/U). Instead of the function, a lookup table may be used. The function (E/U) is defined by using a reference battery having the same or similar characteristics. A set of low and high current or power loads are applied to the reference battery to cause voltage drops which are measured and then used to determine function (E/U). During the operation of the battery, momentary voltage and current (or power) are measured. Afterwards, function (E/U) enables to estimate E. This is a non-real time estimation method which requires less hardware cost and easily achieves a highly accurate measurement.

An idle power consumption P_idle or idle current I_idle may be directly measured by the EM circuitry 3. Currently, it is a challenge to estimate idle power consumption of a battery-operated device due to measurement accuracy of EM circuitry. This is due to a fact that the power consumption of the device during idle operation is low compared to active usage of the device. For example, a mobile device may have the idle power consumption typically well below 40 mW while the active usage may be much higher, e.g. 1500 mW. Often, the current and power measurement features of EM circuitry 3 are optimized to work over all the power and current ranges, and the estimated idle power consumption starts to be at the very low extreme of the accuracy. This means that the measurements of battery voltage, current and the multiplication of both (i.e. power consumption) becomes very difficult. In practice, either the accuracy of power and current measurements is poor or then a special calibration and/or EM circuitry is needed that may raise the costs of manufacturing the device too much. The accuracy of the measurements is device model dependent. It may turn out that the actual power consumption reported by the EM circuitry 3 is too low when compared to the real power consumption during idle status, for example, 2-3 times lower. The actual degree of error depends on the device. Because of errors in this scale, it is impossible to give solid estimations for a true idle power consumption based on the values directly reported by EM circuitry 3. In order to provide reliable estimations for P_idle, the EM circuitry 3 should be fine tuned and calibrated for low power and current consumption. This can be both difficult and expensive.

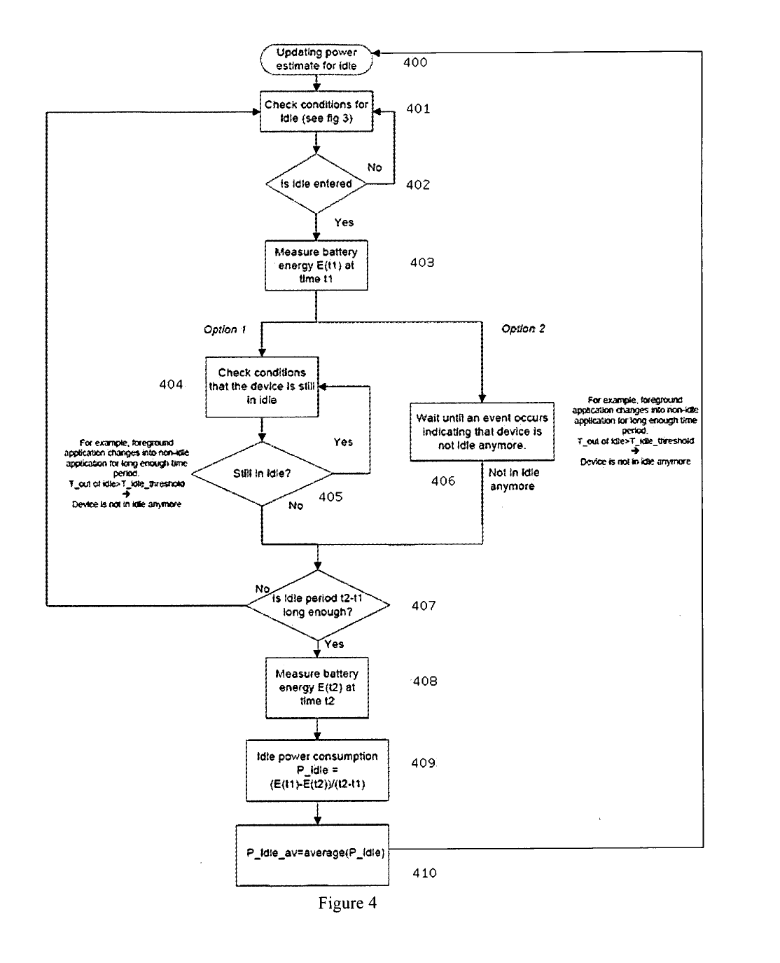

FIG. 4 illustrates another method to determine idle power consumption P_idle with acceptable accuracy, according to an example embodiment of the invention. This way the idle power consumption P_idle is calculated only if the battery level has been truly lowered during the measurement and/or if the battery-operated device 1 has been in idle status longer than a certain time. The energy check in the EM circuitry 3 ensures that the battery really has not been charged during idle status. The time check in the EM circuitry 3 collects time information for different measurement steps and makes sure that the measurement period has been long enough. A long measurement period is useful so that we could get close to higher measurement accuracy. If the mobile has been in idle status for too short time the random deviations in energy level estimate may be too large and any power or other estimations may get distorted.

In step 401, the condition for being idle is checked. Any criteria described above for detecting the idling status may be used. If the condition for being idle is not detected in step 402, the same idle test needs to be done periodically again or based on some event(s). Otherwise, the idle power consumption of the device P_idle is ready to be measured.

If it is detected in step 403 that the device has entered into idle status at time t1, the battery remaining energy is estimated at time t1 based on either real time or non-real time estimation method described above according some examples embodiment, and the energy amount is stored into a memory. It is then continuously checked whether the device is still in idle status. This can be made with various methods, for example, by checking that the foreground application is the idle application and/or other criteria for being idle are still valid in step 405 (Option 1). Step 405 needs to be done periodically until the device is out of idle.

From implementation point of view this can also be made, for example, based on events which indicate that the device is not idle any longer in step 406 (Option 2). Compared to Option 1, Option 2 means that there is no need to do the idle status test periodically and makes the solution more energy effective.

In Option 2, the device itself may report if the foreground application changes to some other application. If this happens it is often good to wait a while before declaring whether the device is still in idle status or not. For example, if a user of a mobile device just presses a key to check the time but does nothing else after that, it can be stated that the device is still in idle status although for a short period of time the foreground application was other than the idle application. The threshold for these interruptions should usually be quite short. Typically, at least, not longer than 2 minutes. What the actual time threshold is depends on the implementation, and can in some cases also be zero, while in some other cases longer than 2 minutes. It is also possible to combine the two options 404 and 406. If Option 2 is used (step 406) there are only two time instants when the battery energy needs to be estimated by the EM circuitry 3, at the moment t1 when the idle status is entered and at the moment t2 when the idle status ends.

Next it is detected in step 407 if the device has been long enough in idle status (i.e. that the time t2−t1 is long enough where t2 is the moment or time instant before the device turns to active), and the remaining energy of battery is estimated at t2 in step 408. In order to estimate P_idle and RIT accurately enough, it is recommended that the device stays in idle mode long enough. What is “long enough” depends on implementation, device and/or hardware setup, and it may be one hour or a whole night. During the tests it has turned out that the minimum “long enough” is one hour. However, for some implementations, devices and/or hardware setups “long enough” may be just a few minutes while for some up to many hours.

After this the idle power can easily be calculated by an equation:

$${P}_{idle} = \frac{E ( t 1 ) - E ( t 2 )}{t 2 - t 1}$$

in step 409. As idle power consumption can be sensitive to even small circuitry measurement variations, it is recommended that the obtained idle power consumption is averaged in step 410. Basically any commonly available averaging method can be used, for example, exponentially running average. Of course, a raw power value can also be used but this may lead into a lot of variation in the obtained idle power consumption value P_idle. After P_idle has been calculated, the power estimation for P_idle is updated in step 400, and the whole process is repeated again after some time interval, for example, after one minute. The repetition can also be based on some event(s) instead of time.

As illustrated in FIG. 2, the RIT is then obtained by

$$RIT ( t ) = \frac{E ( t )}{{P}_{idle\_avg}} ,$$

where E(t) represents the remaining battery energy at a time instant t and is obtained from function (E_i/U_i) mentioned earlier. This function may be called every time when some event takes place, for example, the keypad of device is pressed which indicates that the device is possibly out of idle. This function may also be run in a periodic manner. According to an example of embodiment, the idle power P_idle is obtained for each hour of the day and then the RIT is estimated as

$$RIT ( t ) = \frac{E ( t )}{( {\sum }_{n = 1}^{24} {P}_{idle} ( n ) ) \text{/} 24}$$

Other time intervals for storing the values for P_idle may also be used, e.g. every two hours, or even for every hour of the whole week. It is purely implementation dependent decision what method is chosen. If E(t) is given e.g. in Joules and P_idle_avg in Watts then the remaining idle time RIT will be obtained in seconds. But as mentioned already earlier, it is wiser to convert the seconds to represent days and hours (and possibly minutes) as the remaining idle time is often very long especially with full battery.

Without in any way limiting the scope, interpretation, or application of the claims appearing below, a technical effect of one or more of the example embodiments disclosed herein is to estimate a remaining idle time RIT of battery for a battery-operated device with less hardware costs. Another technical effect of one or more of the example embodiments disclosed herein is to estimate a remaining idle time RIT with high measurement accuracy without tuning or calibrating the EM circuitry.

It will be appreciated that many modifications may be made to the example embodiments described above, for example, the average power consumption and the remaining operating time for other status of device may be determined in the same way as described in the above example embodiment with some understandable variations. It should be realized that the foregoing examples should not be constructed as any limiting.

Embodiments of the present invention may be implemented in software, hardware, application logic or a combination of software, hardware and application logic. The software, application logic and/or hardware may reside in the battery-operated device 1. If desired, part of the software, application logic and/or an instruction set may reside on communication network service. In an example embodiment, the application logic, software and/or an instruction set is maintained on any one of various conventional computer-readable media. In the context of this document, a “computer-readable medium” may be any media or means that can contain, store, communicate, propagate or transport the instructions for use by or in connection with an instruction execution system, apparatus, or device, such as a computing device, with one example of a computing device described and depicted in FIG. 1. A computer-readable medium may comprise a computer-readable storage medium that may be any media or means that can contain or store the instructions for use by or in connection with an instruction execution system, apparatus, or device, such as a computer.

If desired, the different functions discussed herein may be performed in a different order and/or concurrently with each other. Furthermore, if desired, one or more of the above-described functions may be optional or may be combined.

Although various aspects of the invention are set out in the independent claims, other aspects of the invention comprise other combinations of features from the described embodiments and/or the dependent claims with the features of the independent claims, and not solely the combinations explicitly set out in the claims.

It is also noted herein that while the above describes example embodiments of the invention, these descriptions should not be viewed in a limiting sense. Rather, there are several variations and modifications which may be made without departing from the scope of the present invention as defined in the appended claims.

What is claimed is:

1. An apparatus comprising:
a status detector configured to identify status of a device powered by at least one battery,
an energy management circuitry configured to perform
estimating a remaining battery energy at a first time instant and a second time instant, wherein a single status of the device is identified from the first time instant to the second time instant,
calculating an average power consumption based at least on the measured remaining battery energy for at least the first time instant and the second time instant, and
estimating a remaining operating time for the identified status based at least on the calculated average power consumption.

2. An apparatus of claim 1, wherein the status of the device comprising idle status and/or active status.

3. An apparatus of claim 2, wherein the first time instant is when the device enters idle status and the second time instant is when the idle status ends.

4. An apparatus of claim 2, wherein the idle status is detected at least when a power consumption of the battery is less than a predefined power consumption threshold.

5. An apparatus of claim 4, wherein the predefined power consumption threshold are determined based at least on CPU type, or implementation, or device and/or hardware setup.

6. An apparatus of claim 1, wherein the estimated remaining battery energy is provided from a measurement of a momentary voltage and a momentary current.

7. An apparatus of claim 1, wherein the remaining battery energy is estimated based on a real time energy consumption of the at least one battery.

8. An apparatus of claim 7, wherein the real time energy consumption is measured from an integration of power consumption over time drawn from the at least one battery.

9. An apparatus of claim 1, wherein the energy management circuitry is further configured to perform
calculating an average power consumption by dividing a difference between these two measured remaining battery energy for the first time instant and the second time instant by a time difference between the first time instant and the second time instant.

10. An apparatus of claim 9, wherein the calculated power consumption is further averaged by an exponential running average function.

11. A computer program product comprising a computer-readable medium bearing computer program code embodied therein for use with a computer, the computer program code comprising:
code for estimating a remaining battery energy for a first time instant and a second time instant, wherein a single status of the device is identified from the first time instant to the second time instant,
code for calculating an average power consumption based partially at least on the measured remaining battery energy for at least the first time instant and the second time instant, and
code for estimating a remaining operating time for the identified status based partially at least on the calculated average power consumption.

12. A method comprising:
identifying status of a battery,
estimating a remaining battery energy at a first time instant and a second time instant, wherein a single status of the device is identified from the first time instant to the second time instant,
calculating an average power consumption based at least on the measured remaining battery energy, and
estimating a remaining operating time for the identified status based at least on the calculated average power consumption.

13. A method according to claim 12, wherein the status of the device include at least idle status and active status.

14. A method according to claim 13, wherein the first time instant is when the device enters idle status and the second time instant is when the idle status ends.

15. A method of claim 13, wherein the idle status is detected at least when a power consumption of the battery is less than a predefined power consumption threshold.

16. A method of claim 12, wherein the estimated remaining battery energy is provided from a measurement of a momentary voltage and a momentary current.

17. A method of claim 12, wherein the remaining battery energy is estimated based on a real time energy consumption of the at least one battery, the real time energy consumption is measured from an integration of power consumption over time drawn from the at least one battery.

18. A method of claim 12, the energy management circuitry further configured to perform
calculating an average power consumption by dividing a difference between these two measured remaining battery energy for the first and the second time instant by a time difference between the first and the second time instant.

19. A method of claim 12, the calculated power consumption is further averaged by an exponential running average function.

20. An apparatus, comprising:
means for identifying status of a device powered by at least one power storage means,
means for estimating a remaining energy of the power storage means for a first time instant and a second time instant, wherein a single status of the device is identified from the first time instant to the second time instant,
means for calculating an average power consumption based at least on the measured remaining battery energy for at least the first time instant and the second time instant, and
means for estimating a remaining operating time for the identified status based at least on the calculated average power consumption.
